(19) United States
(12) Patent Application Publication
(10) Pub. No.: US 2017/0338215 A1
(43) Pub. Date: Nov. 23, 2017

(54) HETEROGENEOUS CELL ARRAY

(71) Applicant: QUALCOMM Incorporated, San Diego, CA (US)

(72) Inventors: Stanley Seungchul Song, San Diego, CA (US); Giridhar Nallapati, San Diego, CA (US); Da Yang, San Diego, CA (US); Kern Rim, San Diego, CA (US); Robert Bucki, Raleigh, NC (US); Choh Fei Yeap, Hsinchu City (TW)

(21) Appl. No.: 15/160,992

(22) Filed: May 20, 2016

(51) Int. Cl. H01L 27/02; H01L 27/092; H01L 27/118

(52) U.S. Cl. CPC H01L 27/0207; H01L 27/11803; H01L 27/0924; H01L 2027/11809; H01L 2027/11874; H01L 2027/11881; H01L 2027/11824

(57) ABSTRACT

A heterogeneous cell array includes a first column of cells and a second column of cells. The first column of cells includes a first cell having a first area and a second cell having the first area. The first cell includes two fin-type field effect transistors having a first number of fins and the second cell includes two fin-type field effect transistors having the first number of fins. The second column of cells includes a third cell having a second area. The third cell is adjacent to the first cell and to the second cell, and the third cell includes two fin-type field effect transistors having a second number of fins. The second area is greater than the first area, and the second number of fins is greater than the first number of fins.

### I. FIELD

The present disclosure is generally related to a cell array.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Wireless telephones may include cell arrays that are comprised of different cells. Typically, each cell in a cell array has the same area. As used herein, the “area” of a data cell is defined by the product of a width of the data cell and a length of the data cell. A standard cell array may include multiple columns and multiple rows. Each cell in the cell array may be located by a particular row and a particular column. Each cell in the standard cell array may include two fin-type field effect transistors (fin-FETs) having a similar number of fins (e.g., “fingers”). As a non-limiting example, each cell in the standard cell array may include two two-finger fin-FETs. If a particular cell requires a larger driving current (e.g., source-to-drain current) than a cell having two-finger fin-FETs, the particular cell may require fin-FETs with a larger number of fins. However, the number of fins for a fin-FET may be limited by the cell area.

### SUMMARY

According to one implementation of the present disclosure, a heterogeneous cell array includes a first column of cells and a second column of cells. The first column of cells includes a first cell having a first area and a second cell having the first area. The first cell includes two fin-type field effect transistors having a first number of fins and the second cell includes two fin-type field effect transistors having the first number of fins. The second column of cells includes a third cell having a second area. The third cell is adjacent to the first cell and to the second cell, and the third cell includes two fin-type field effect transistors having a second number of fins. The second area is greater than the first area, and the second number of fins is greater than the first number of fins.

According to another implementation of the present disclosure, a method for forming a heterogeneous cell array includes forming a first column of cells and forming a second column of cells. The first column of cells includes a first cell having a first area and a second cell having the first area. The first cell includes two fin-type field effect transistors having a first number of fins and the second cell includes two fin-type field effect transistors having the first number of fins. The second column of cells includes a third cell having a second area. The third cell is adjacent to the first cell and to the second cell, and the third cell includes two fin-type field effect transistors having a second number of fins. The second area is greater than the first area, and the second number of fins is greater than the first number of fins.

According to another implementation of the present disclosure, a non-transitory computer-readable medium includes commands for forming a heterogeneous cell array. The commands, when executed by a fabrication device, cause the fabrication device to perform operations including forming a first column of cells and forming a second column of cells. The first column of cells includes a first cell having a first area and a second cell having the first area. The first cell includes two fin-type field effect transistors having a first number of fins and the second cell includes two fin-type field effect transistors having the first number of fins. The second column of cells includes a third cell having a second area. The third cell is adjacent to the first cell and to the second cell, and the third cell includes two fin-type field effect transistors having a second number of fins. The second area is greater than the first area, and the second number of fins is greater than the first number of fins.

According to another implementation of the present disclosure, a heterogeneous cell array includes a first column and a second column. The first column includes first means for aligning circuit components to a power grid having a first area and second means for aligning circuit components to the power grid having the first area. The first means for aligning circuit components to the power grid includes two fin-type field effect transistors having a first number of fins and the second means for aligning circuit components to the power grid includes two fin-type field effect transistors having the first number of fins. The second column includes third means for aligning circuit components to the power grid having a second area. The third means for aligning circuit components to the power grid is adjacent to the first means for aligning circuit components to the power grid and to the second means for aligning circuit components to the power grid, and the third means for aligning circuit components to the power grid includes two fin-type field effect transistors having a second number of fins. The second area is greater than the first area, and the second number of fins is greater than the first number of fins.

### IV. BRIEF DESCRIPTION OF THE DRAWINGS

FIG. 1 shows a top view of a heterogeneous cell array;

FIG. 2 shows a top view of a two-fin p-type metal oxide semiconductor (PMOS) fin-type field effect transistor of the heterogeneous cell array of FIG. 1;

FIG. 3 shows a top view of a two-fin n-type metal oxide semiconductor (NMOS) fin-type field effect transistor of the heterogeneous cell array of FIG. 1;

FIG. 4 shows a top view of a four-fin PMOS fin-type field effect transistor of the heterogeneous cell array of FIG. 1;

FIG. 5 shows a top view of a four-fin NMOS fin-type field effect transistor of the heterogeneous cell array of FIG. 1;

FIG. 6 shows the top view of the heterogeneous cell array of FIG. 1 with power grid lines;

FIG. 7 shows a top view of another heterogeneous cell array;

FIG. 8 shows the top view of the heterogeneous cell array of FIG. 7 with power grid lines;

FIG. 9 is a flowchart of a method for fabricating a heterogeneous cell array;

FIG. 10 is a block diagram of a device including the heterogeneous cell array of

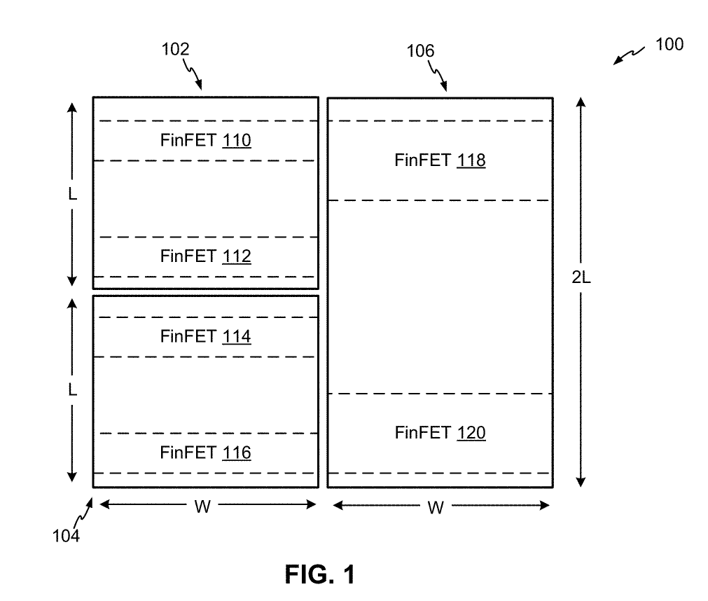

FIG. 1; and

FIG. 11 is a data flow diagram of a manufacturing process to manufacture electronic devices that include the heterogeneous cell array of FIG. 1.

### V. DETAILED DESCRIPTION

Referring to FIG. 1, a top view of a heterogeneous cell array 100 is shown. The heterogeneous cell array 100 includes a first column of cells and a second column of cells. The first column of cells includes a first cell 102 having a first length (L) and a second cell 104 having the first length (L). The first cell 102 has a width (W) and the second cell 104 has the width (W). The second column of cells includes a third cell 106 having a second length (2L) and the width (W). The second length (2L) is greater than the first length (L). For example, the second length (2L) may be twice the first length (L). Thus, the first cell 102 and the second cell 104 may have a first area, and the third cell 106 may have a second area that is greater than the first area. The first area may be substantially rectangular having the first length (L) and the width (W), and the second area may be substantially rectangular having the second length (2L) and the width (W).

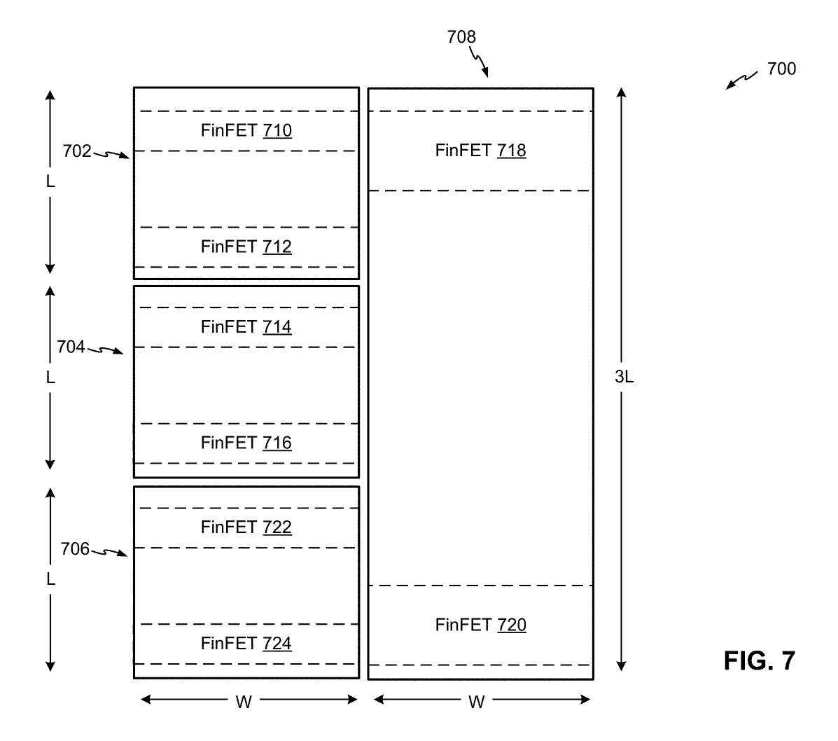

Although the first column of cells is depicted as having two cells 102, 104 and the second column of cells is depicted as having a single cell 106, in other implementations, each column of cells may have additional cells. As a non-limiting example, the first column of cells may include ten cells and the second column of cells may include five cells. Accordingly, each cell in the second column of cells may be twice the length of each cell in the first column of cells. An illustrative non-limiting example of another implementation of a heterogeneous cell array with a different cell configuration is shown in FIG. 7.

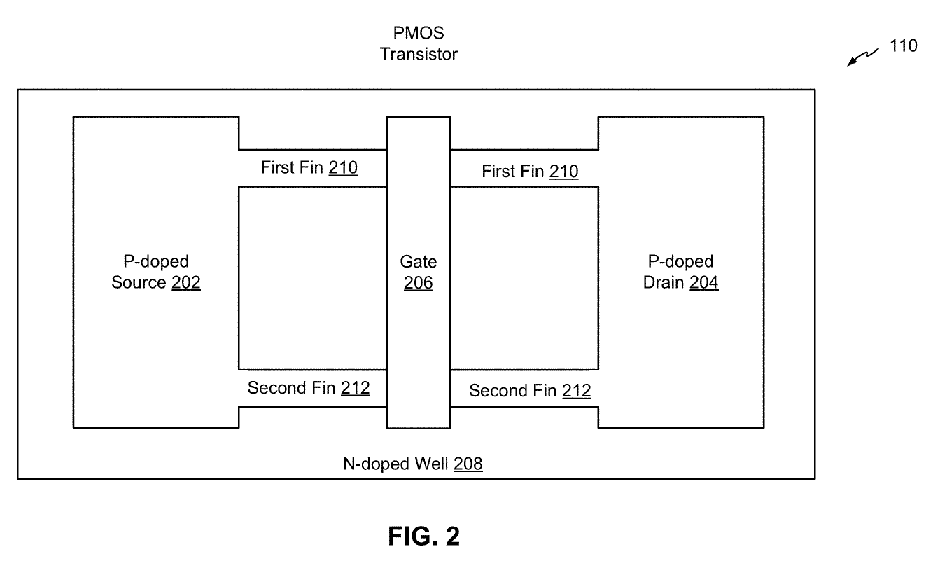

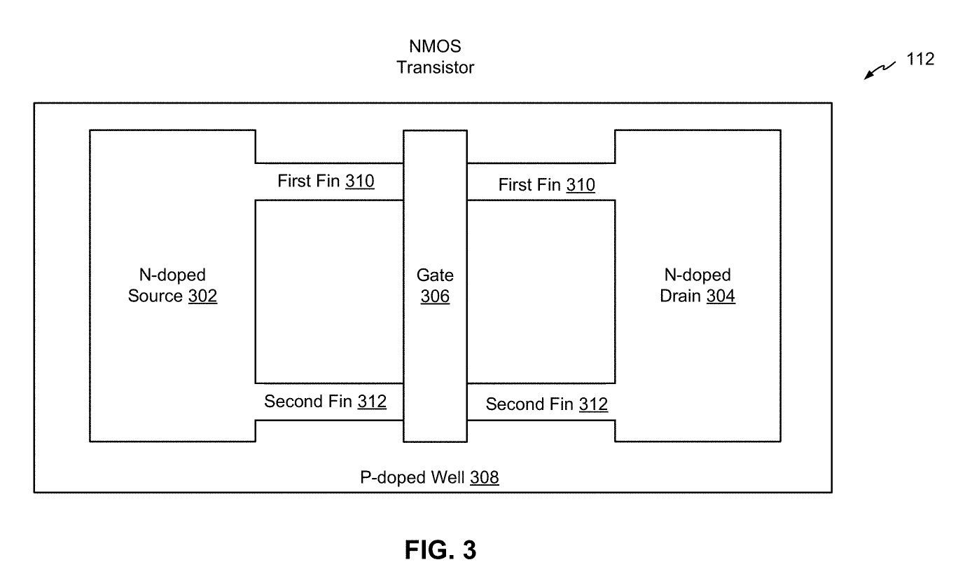

The first cell 102 includes two fin-type field effect transistors (FinFETs). For example, the first cell 102 includes a fin-type field effect transistor 110 and a fin-type field effect transistor 112. According to one implementation, the fin-type field effect transistor 110 may be a p-type metal oxide semiconductor (PMOS) transistor, and the fin-type field effect transistor 112 may be an n-type metal oxide semiconductor (NMOS) transistor. Each fin-type field effect transistor 110, 112 may have a first number of fins, as described in greater detail with respect to FIGS. 2-3. For example, each fin-type field effect transistor 110, 112 may include two fins.

The second cell 104 also includes two fin-type field effect transistors. For example, the second cell 104 includes a fin-type field effect transistor 114 and a fin-type field effect transistor 116. According to one implementation, the fin-type field effect transistor 114 may be an NMOS transistor, and the fin-type field effect transistor 116 may be a PMOS transistor. Each fin-type field effect transistor 114, 116 may have the first number of fins, as described in greater detail with respect to FIGS. 2-3. For example, each fin-type field effect transistor 114, 116 may include two fins.

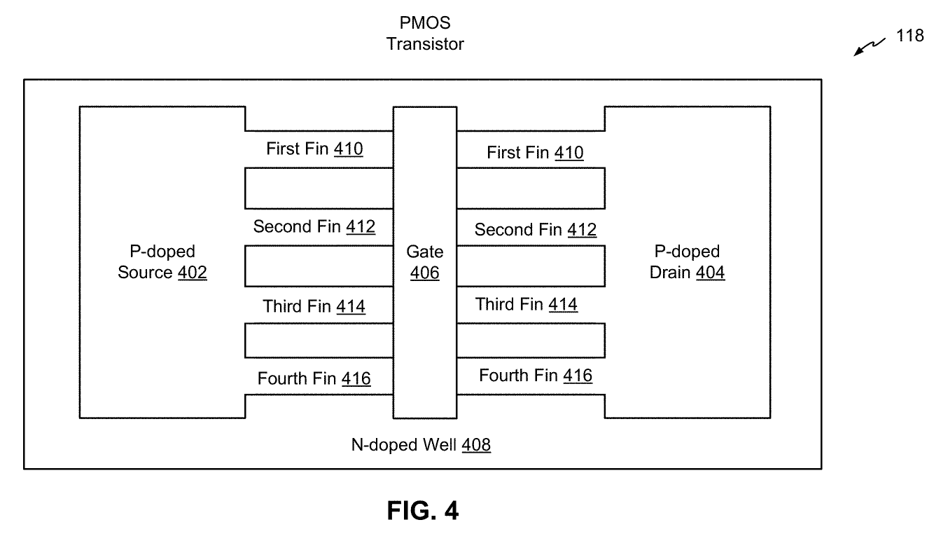

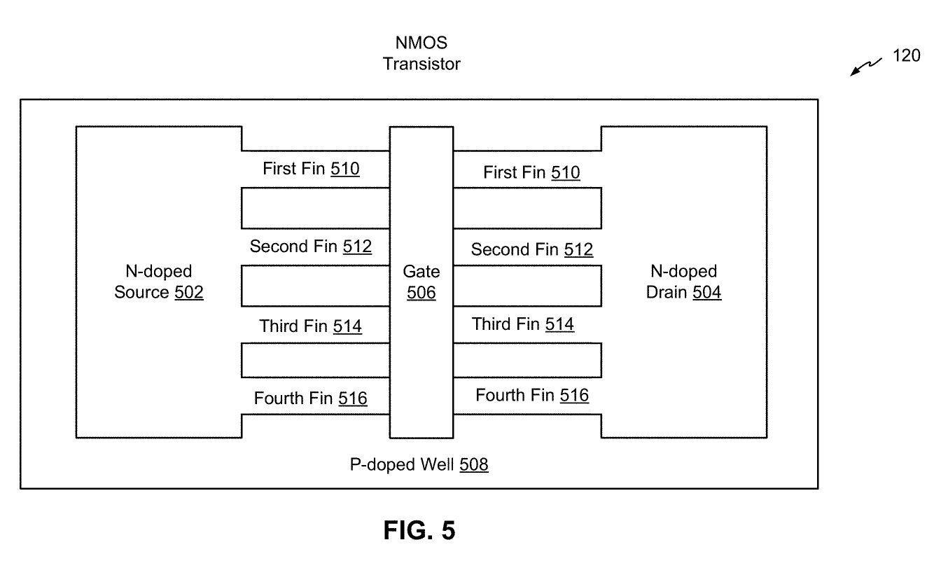

The third cell 106 includes two fin-type field effect transistors. For example, the third cell 106 includes a fin-type field effect transistor 118 and a fin-type field effect transistor 120. According to one implementation, the fin-type field effect transistor 118 may be a PMOS transistor, and the fin-type field effect transistor 120 may be an NMOS transistor. Each fin-type field effect transistor 118, 120 may have a second number of fins, as described in greater detail with respect to FIGS. 4-5. For example, each fin-type field effect transistor 118, 120 may include four fins. Thus, the second number of fins may be greater than the first number of fins.

The heterogeneous cell array 100 of FIG. 1 may enable different cells to have different driving currents. For example, because the third cell 106 includes two four-finger transistors (e.g., two fin-type field effect transistors 118, 120 having four fins) as opposed to two two-finger transistors, the third cell 106 may have a larger driving current than the other cells 102, 104. To illustrate, the driving current between a source and a drain of the fin-type field effect transistor 118 may be larger than the driving current between a source and a drain of the fin-type field effect transistor 110. The architecture of the cells 102, 104, 106 in the heterogeneous cell array 100 may enable the third cell 106 to have a substantially larger driving current than the other cells. For example, because the second length (2L) of the third cell 106 is twice the first length (L) of the other cells 102, 104 (resulting in the second area being approximately twice the first area), the fin-type field effect transistors 118, 120 of the third cell 106 may have additional fins to increase the driving current of the third cell 106.

Referring to FIG. 2, a particular implementation of the fin-type field effect transistor 110 is shown. The fin-type field effect transistor 110 is a two-finger transistor (e.g., a two-fin transistor). Although the fin-type field effect transistor 110 is shown in FIG. 2, it should be understood that the fin-type field effect transistor 116 may have a similar configuration (e.g., “layout”).

The fin-type field effect transistor 110 includes a source 202, a drain 204, a gate 206, and a well 208. The fin-type field effect transistor 110 may be a PMOS transistor and have an n-doped well 208 with p-doped source and drains 202, 204. Two fins 210, 212 (e.g., two fingers) couple the source 202 to the drain 204. The gate 206 is positioned over the two fins 210, 212. The source 202, the drain 204, the gate 206, and the fins 210, 212 are positioned in the well 208. The fin-type field effect transistor 110 may have a relatively small driving current due to having a relatively small number of fins (e.g., two fins). For example, a relatively small amount of positive charge carriers (e.g., “holes”) may flow between the source 202 and the drain 204 along the two fins 210, 212.

Referring to FIG. 3, a particular implementation of the fin-type field effect transistor 112 is shown. The fin-type field effect transistor 112 is a two-finger transistor (e.g., a two-fin transistor). Although the fin-type field effect transistor 112 is shown in FIG. 3, it should be understood that the fin-type field effect transistor 114 may have a similar configuration (e.g., “layout”).

The fin-type field effect transistor 112 includes a source 302, a drain 304, a gate 306, and a well 308. The fin-type field effect transistor 112 may be an NMOS transistor and have a p-doped well 308 with n-doped source and drains 302, 304. Two fins 310, 312 (e.g., two fingers) couple the source 302 to the drain 304. The gate 306 is positioned over the two fins 310, 312. The source 302, the drain 304, the gate 306, and the fins 310, 312 are positioned in the well 308. The fin-type field effect transistor 112 may have a relatively small driving current due to having a relatively small number of fins (e.g., two fins). For example, a relatively small amount of negative charge carriers (e.g., electrons) may flow between the source 302 and the drain 304 along the two fins 310, 312.

Referring to FIG. 4, a particular implementation of the fin-type field effect transistor 118 is shown. The fin-type field effect transistor 118 is a four-finger transistor (e.g., a four-fin transistor).

The fin-type field effect transistor 118 includes a source 402, a drain 404, a gate 406, and a well 408. The fin-type field effect transistor 118 may be a PMOS transistor and have an n-doped well 408 with p-doped source and drains 402, 404. Four fins 410, 412, 414, 416 (e.g., four fingers) couple the source 402 to the drain 404. The gate 406 is positioned over the four fins 410, 412, 414, 416. The source 402, the drain 404, the gate 406, and the fins 410, 412, 414, 416 are positioned in the well 408. The fin-type field effect transistor 118 may have a relatively large driving current due to having a relatively large number of fins (e.g., four fins). For example, a relatively large amount of positive charge carriers (e.g., holes) may flow between the source 402 and the drain 404 along the four fins 410, 412, 414, 416.

Referring to FIG. 5, a particular implementation of the fin-type field effect transistor 120 is shown. The fin-type field effect transistor 120 is a four-finger transistor (e.g., a four-fin transistor).

The fin-type field effect transistor 120 includes a source 502, a drain 504, a gate 506, and a well 508. The fin-type field effect transistor 120 may be an NMOS transistor and have a p-doped well 508 with n-doped source and drains 502, 504. Four fins 510, 512, 514, 516 (e.g., four fingers) couple the source 502 to the drain 504. The gate 506 is positioned over the four fins 510, 512, 514, 516. The source 502, the drain 504, the gate 506, and the fins 510, 512, 514, 516 are positioned in the well 508. The fin-type field effect transistor 120 may have a relatively large driving current due to having a relatively large number of fins (e.g., four fins). For example, a relatively large amount of negative charge carriers (e.g., electrons) may flow between the source 502 and the drain 504 using the four fins 510, 512, 514, 516.

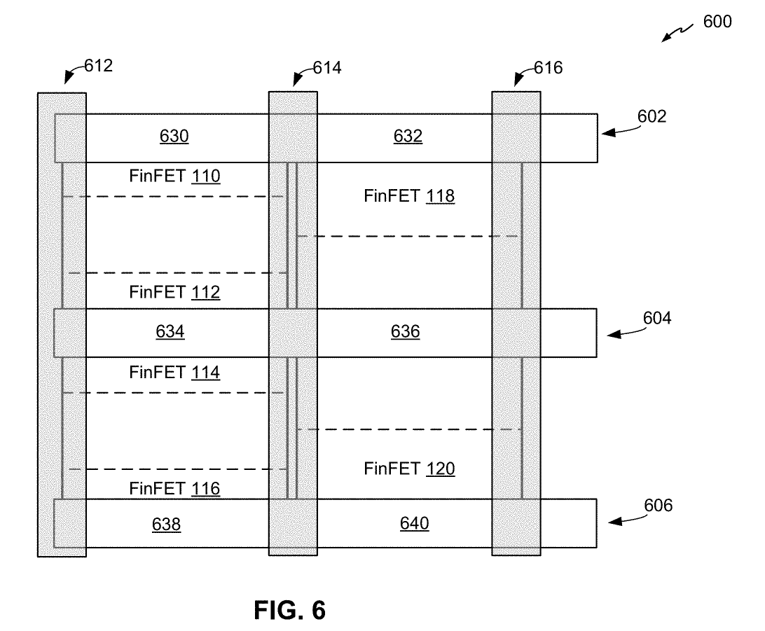

Referring to FIG. 6, a top view of a heterogeneous cell array 600 is shown. The heterogeneous cell array 600 includes the components of the heterogeneous cell array 100 of FIG. 1. Additionally, the heterogeneous cell array 600 includes a metal layer 602, a metal layer 604, and a metal layer 606.

Each metal layer 602, 604, 606 may be “cut” according to power grid cut patterns 612, 614, 614 to form power grid lines. To illustrate, the metal layer 602 may be cut according to the power grid cut patterns 612, 614, 616 to form a power grid line 630 and a power grid line 632. The power grid line 630 and the power grid line 632 may have a logical low voltage level. For example, the power grid lines 630, 632 may be coupled to ground (Vss). The power grid line 630 may be coupled to the fin-type field effect transistor 110, and the power grid line 632 may be coupled to the fin-type field effect transistor 118. In another implementation, because the power grid lines 630, 632 have the same voltage level, the power grid cut pattern 614 may be shortened such that the power grid lines 630, 632 are a common line.

The metal layer 604 may be cut according to the power grid cut patterns 612, 614, 616 to form a power grid line 634 and a power grid line 636. The power grid line 634 and the power grid line 636 may have a logical high voltage level. For example, the power grid lines 634, 636 may be coupled to a supply voltage (Vdd). The power grid line 634 may be coupled to the fin-type field effect transistors 112, 114. Alternatively, the power grid line 636 may not be coupled to the supply voltage (Vdd) and may be allowed to “float”. In another implementation, because the power grid lines 634, 636 have the same voltage level, the power grid cut pattern 614 may be shortened such that the power grid lines 634, 636 are a common line.

The metal layer 606 may be cut according to the power grid cut patterns 612, 614, 616 to form a power grid line 638 and a power grid line 640. The power grid line 638 may have a logical low voltage level, and the power grid line 640 may have a logical high voltage level. For example, the power grid line 638 may be coupled to ground (Vss), and the power grid line 640 may be coupled to the supply voltage (Vdd). The power grid line 638 may be coupled to the fin-type field effect transistor 116, and the power grid line 640 may be coupled to the fin-type field effect transistor 120.

The topology of the heterogeneous cell array 600 may enable traditional power grid lines to be coupled to the fin-type field effect transistors 110, 112, 114, 116, 118, 120 although the fin-type field effect transistors 110, 112, 114, 116 and the fin-type field effect transistors 118, 120 have different cell alignments. As a result, fin-type field effect transistors having different cell alignments may be coupled to power grids using simpler manufacturing techniques with reduced design complexity.

Referring to FIG. 7, a top view of a heterogeneous cell array 700 is shown. The heterogeneous cell array 100 includes a first column of cells and a second column of cells. The first column of cells includes a first cell 702 having a first length (L), a second cell 704 having the first length (L), and a third cell 706 having the first length (L). The first cell 702 has a width (W), the second cell 704 has the width (W), and the third cell 706 has the width (W). The second column of cells includes a fourth cell 708 having a second length (3L) and the width (W). The second length (3L) is greater than the first length (3L). For example, the second length (3L) may be three times the first length (L). Thus, each cells 702, 704, 706 may have a first area, and the fourth cell 708 may have a second area that is greater than the first area. The first area may be substantially rectangular having the first length (L) and the width (W), and the second area may be substantially rectangular having the second length (3L) and the width (W).

The first cell 702 includes two fin-type field effect transistors. For example, the first cell 702 includes a fin-type field effect transistor 710 and a fin-type field effect transistor 712. The fin-type field effect transistor 710 may have a substantially similar architecture as the fin-type field effect transistor 110 of FIG. 2, and the fin-type field effect transistor 712 may have a substantially similar architecture as the fin-type field effect transistor 112 of FIG. 3.

The second cell 704 also includes two fin-type field effect transistors. For example, the second cell 704 includes a fin-type field effect transistor 714 and a fin-type field effect transistor 716. The fin-type field effect transistor 714 may have a substantially similar architecture as the fin-type field effect transistor 112 of FIG. 3, and the fin-type field effect transistor 716 may have a substantially similar architecture as the fin-type field effect transistor 110 of FIG. 2.

The third cell 706 includes two fin-type field effect transistors. For example, the third cell 706 includes a fin-type field effect transistor 722 and a fin-type field effect transistor 724. The fin-type field effect transistor 722 may have a substantially similar architecture as the fin-type field effect transistor 110 of FIG. 2, and the fin-type field effect transistor 724 may have a substantially similar architecture as the fin-type field effect transistor 112 of FIG. 3.

The fourth cell 708 includes two fin-type field effect transistors. For example, the fourth cell 708 includes a fin-type field effect transistor 718 and a fin-type field effect transistor 720. The fin-type field effect transistor 718 may have a substantially similar architecture as the fin-type field effect transistor 118 of FIG. 4, and the fin-type field effect transistor 720 may have a substantially similar architecture as the fin-type field effect transistor 120 of FIG. 5.

The heterogeneous cell array 700 of FIG. 7 may enable different cells to have different driving currents. For example, because the fourth cell 708 includes two four-finger transistors (e.g., two fin-type field effect transistors 718, 720 having four fins) as opposed to two two-finger transistors, the fourth cell 708 may have a larger driving current than the other cells 702, 704, 706. To illustrate, the driving current between a source and a drain of the fin-type field effect transistor 718 may be larger than the driving current between a source and a drain of the fin-type field effect transistor 710. The architecture of the cells 702, 704, 706, 708 in the heterogeneous cell array 700 may enable the fourth cell 708 to have a substantially larger driving current than the other cells. For example, because the length (3L) of the fourth cell 708 is three times the length (L) of the other cells 702, 704, 706, the fin-type field effect transistors 718, 720 of the fourth cell 708 may have additional fins to increase the driving current of the fourth cell 708.

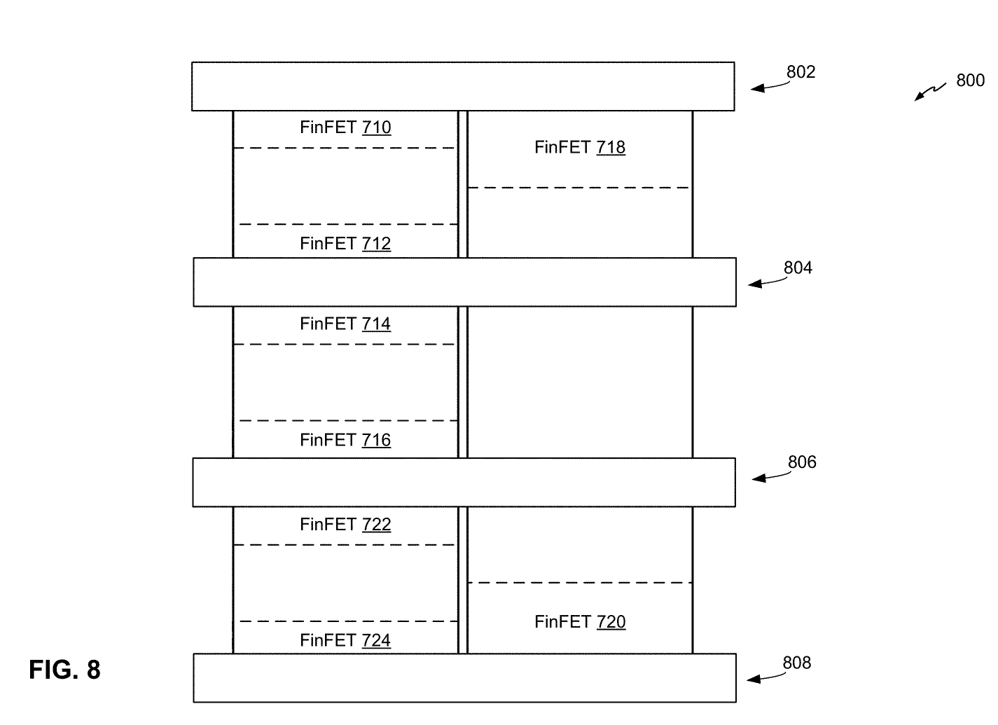

Referring to FIG. 8, a top view of a heterogeneous cell array 800 is shown. The heterogeneous cell array 800 includes the components of the heterogeneous cell array 700 of FIG. 7. Additionally, the heterogeneous cell array 800 includes a metal layer 802, a metal layer 804, a metal layer 806, and a metal layer 808.

Each metal layer 802, 804, 806, 808 may be a power grid line. The metal layer 802 may be coupled to the fin-type field effect transistor 710 and to the fin-type field effect transistor 718. The metal layer 802 may have a logical low voltage level. For example, the metal layer 802 may be coupled to ground (Vss). The metal layer 804 may be coupled to the fin-type field effect transistor 712 and to the fin-type field effect transistor 714. The metal layer 804 may have a logical high voltage level. For example, the metal layer 804 may be coupled to a supply voltage (Vdd).

The metal layer 806 may be coupled to the fin-type field effect transistor 716 and to the fin-type field effect transistor 722. The metal layer 806 may have a logical low voltage level. For example, the metal layer 806 may be coupled to ground (Vss). The metal layer 808 may be coupled to the fin-type field effect transistor 720 and to the fin-type field effect transistor 724. The metal layer 808 may have a logical high voltage level. For example, the metal layer may be coupled to the supply voltage (Vdd).

The topology of the heterogeneous cell array 800 may enable traditional power grid lines to be coupled to the fin-type field effect transistors 710-724 although the fin-type field effect transistors 710, 712, 714, 716, 722, 724 and the fin-type field effect transistors 718, 720 have different cell alignments. As a result, fin-type field effect transistors having different cell alignments may be coupled to power grids using simpler manufacturing techniques with reduced design complexity.

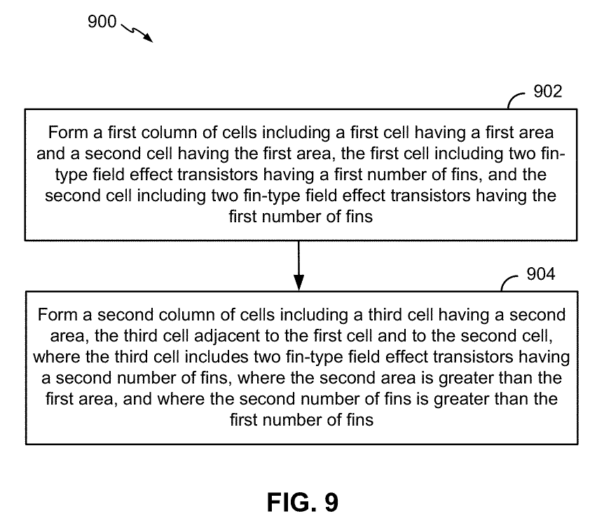

Referring to FIG. 9, a flowchart of a method 900 of fabricating a heterogeneous cell array is depicted. The method 900 may be performed using the fabrication equipment of FIG. 11. The method 900 may be used to fabricate one or more of the heterogeneous cell arrays 100, 600, 700, 800 of FIGS. 1 and 6-8.

The method 900 includes forming a first column of cells including a first cell having a first area and a second cell having the first area, at 902. The first cell may include two fin-type field effect transistors having a first number of fins, and the second cell may include two fin-type field effect transistors having the first number of fins. As a non-limiting example, referring to FIG. 1, fabrication equipment may form the first column of cells including the first cell 102 having the first area and the second cell 104 having the first area. The first area may be substantially rectangular having the first length (L) and the width (W). The first cell 102 includes two fin-type field effect transistors 110, 112 having two fins, and the second cell 104 includes two fin-type field effect transistors 114, 116 having two fins.

The method 900 also includes forming a second column of cells including a third cell having a second area, at 904. The third cell may be adjacent to the first cell and to the second cell, and the third cell may include two fin-type field effect transistors having a second number of fins. The second area may be greater than the first area, and the second number of fins may be greater than the first number of fins. As a non-limiting example, referring to FIG. 1, fabrication equipment may form the second column of cells including the third cell 106 having the second area. The second area may be substantially rectangular having the second length (2L or 3L) and the width (W). The third cell 106 may be adjacent to the first cell 102 and to the second cell 104, and the third cell 106 may include two fin-type field effect transistors 118, 120 having four fins. According to one implementation 900, the second area is twice the first area. According to another implementation of the method 900, the second area is three times the first area.

The heterogeneous cell array fabricated according to the method 900 may also include a first power grid line coupled to a first p-type metal oxide semiconductor transistor of the first cell and to a third p-type metal oxide of the third cell. The heterogeneous cell array may also include a second power grid line coupled to a first n-type metal oxide semiconductor transistor of the first cell and to a second n-type metal oxide semiconductor transistor of the second cell. The heterogeneous cell array may further include a third power grid line coupled to a second p-type metal oxide semiconductor transistor of the second cell. The heterogeneous cell array may also include a fourth power grid line coupled to a third n-type metal oxide semiconductor transistor of the third cell. Illustrative examples of the power lines are shown with respect to FIG. 6.

The method 900 of FIG. 9 may enable different cells to have different driving currents. For example, because the third cell 106 includes two four-finger transistors (e.g., two fin-type field effect transistors 118, 120 having four fins) as opposed to two two-finger transistors, the third cell 106 may have a larger driving current than the other cells 102, 104. To illustrate, the driving current between a source and a drain of the fin-type field effect transistor 118 may be larger than the driving current between a source and a drain of the fin-type field effect transistor 110. The architecture of the cells 102, 104, 106 in the heterogeneous cell array 100 may enable the third cell 106 to have a substantially larger driving current than the other cells. For example, because the second area of the third cell 106 is twice the first area of the other cells 102, 104, the fin-type field effect transistors 118, 120 of the third cell 106 may have additional fins to increase the driving current of the third cell 106.

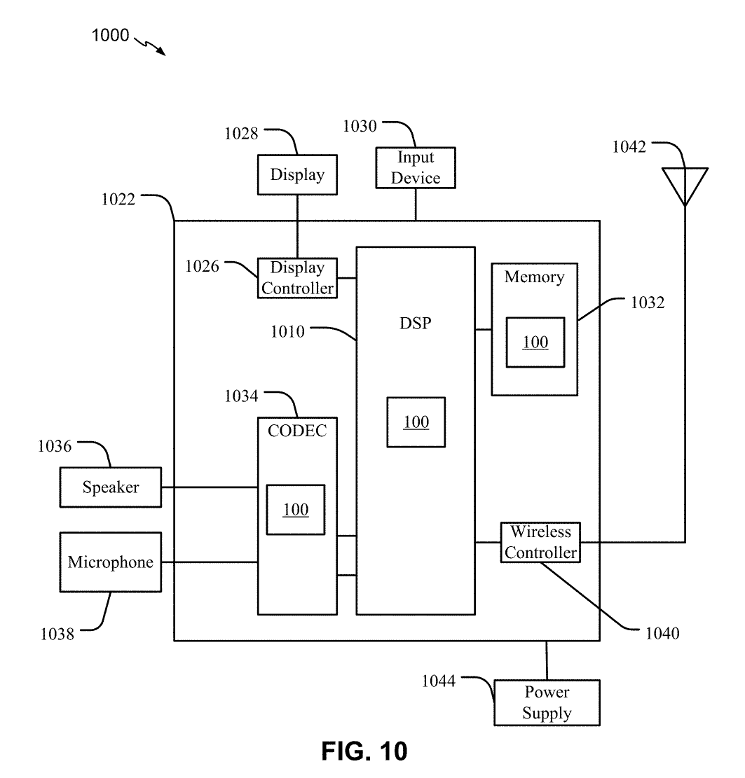

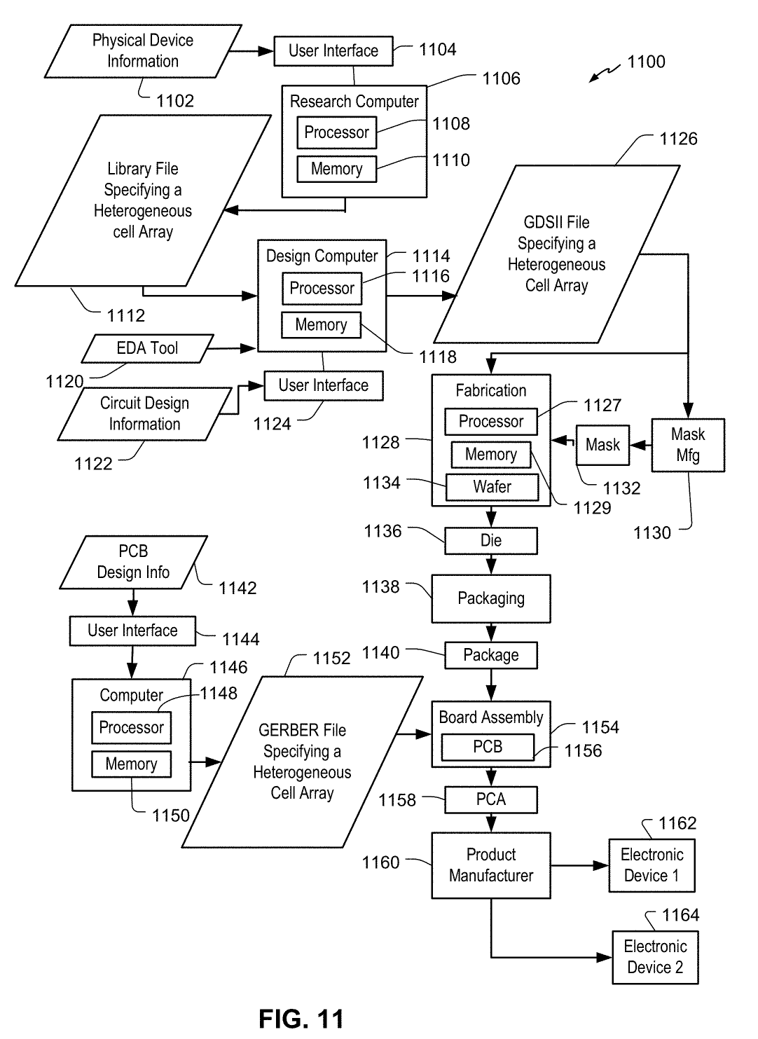

Referring to FIG. 10, a block diagram of a device 1000 is depicted. The device 1000 includes a processor, such as a digital signal processor (DSP) 1010, coupled to a memory 1032. The memory 1032 may include the heterogeneous cell array 100 of FIG. 1. FIG. 10 also shows a display controller 1026 that is coupled to the digital signal processor 1010 and to a display 1028. A coder/decoder (CODEC) 1034 can also be coupled to the digital signal processor 1010. A speaker 1036 and a microphone 1038 can be coupled to the CODEC 1034. According to some implementations, the heterogeneous cell array 100 may be in other components of the device 1000. As non-limiting examples, the heterogeneous cell array 100 may be located in the digital signal processor 1010, the CODEC 1034, or both.

FIG. 10 also indicates that a wireless controller 1040 can be coupled to the digital signal processor 1010 and to an antenna 1042. In a particular implementation, the DSP 1010, the display controller 1026, the memory 1032, the CODEC 1034, and the wireless controller 1040 are included in a system-in-package or system-on-chip device 1022. In a particular implementation, an input device 1030 and a power supply 1044 are coupled to the system-on-chip device 1022. Moreover, in a particular implementation, as illustrated in FIG. 10, the display 1028, the input device 1030, the speaker 1036, the microphone 1038, the antenna 1042, and the power supply 1044 are external to the system-on-chip device 1022. However, each of the display 1028, the input device 1030, the speaker 1036, the microphone 1038, the antenna 1042, and the power supply 1044 can be coupled to a component of the system-on-chip device 1022, such as an interface or a controller.

In conjunction with the described implementations, a heterogeneous cell array includes a first column and a second column. The first column includes first means for aligning circuit components to a power grid having a first area and second means for aligning circuit components to the power grid having the first area. For example, the first means for aligning circuit components to the power grid may include the first cell 102 of FIGS. 1 and 6, or the first cell 702 of FIGS. 7 and 8. The first means for aligning circuit components to the power grid may include two fin-type field effect transistors having a first number of fins. The second means for aligning circuit components to the power grid may include the second cell 104 of FIGS. 1 and 6, or the first cell 704 of FIGS. 7 and 8. The second means for aligning circuit components to the power grid may include two fin-type field effect transistors having the first number of fins.

The second column may include third means for aligning circuit components to the power grid having a second area. For example, the third means for aligning circuit components to the power grid may include the third cell 106 of FIGS. 1 and 6, or the fourth cell 708 of FIGS. 7 and 8. The third means for aligning circuit components to the power grid may be adjacent to the first means for aligning circuit components to the power grid and to the second means for aligning circuit components to the power grid. The third means for aligning circuit components to the power grid may include two fin-type field effect transistors having a second number of fins. The second area may be greater than the first area, and the second number of fins may be greater than the first number of fins.

The foregoing disclosed devices and functionalities may be designed and configured into computer files (e.g. RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 11 depicts a particular illustrative implementation of an electronic device manufacturing process 1100.

Physical device information 1102 is received at the manufacturing process 1100, such as at a research computer 1106. The physical device information 1102 may include design information representing at least one physical property of a semiconductor device, such as the heterogeneous cell array 100 of FIG. 1. For example, the physical device information 1102 may include physical parameters, material characteristics, and structure information that is entered via a user interface 1104 coupled to the research computer 1106. The research computer 1106 includes a processor 1108, such as one or more processing cores, coupled to a computer readable medium such as a memory 1110. The memory 1110 may store computer readable instructions that are executable to cause the processor 1108 to transform the physical device information 1102 to comply with a file format and to generate a library file 1112.

In a particular implementation, the library file 1112 includes at least one data file including the transformed design information. For example, the library file 1112 may include a library of semiconductor devices including a device that includes the heterogeneous cell array 100 of FIG. 1, that is provided for use with an electronic design automation (EDA) tool 1120.

The library file 1112 may be used in conjunction with the EDA tool 1120 at a design computer 1114 including a processor 1116, such as one or more processing cores, coupled to a memory 1118. The EDA tool 1120 may be stored as processor executable instructions at the memory 1118 to enable a user of the design computer 1114 to design a circuit including the heterogeneous cell array 100 of FIG. 1, of the library file 1112. For example, a user of the design computer 1114 may enter circuit design information 1122 via a user interface 1124 coupled to the design computer 1114. The circuit design information 1122 may include design information representing at least one physical property of a semiconductor device, such as the heterogeneous cell array 100 of FIG. 1. To illustrate, the circuit design property may include identification of particular circuits and relationships to other elements in a circuit design, positioning information, feature size information, interconnection information, or other information representing a physical property of a semiconductor device.

The design computer 1114 may be configured to transform the design information, including the circuit design information 1122, to comply with a file format. To illustrate, the file formation may include a database binary file format representing planar geometric shapes, text labels, and other information about a circuit layout in a hierarchical format, such as a Graphic Data System (GDSII) file format. The design computer 1114 may be configured to generate a data file including the transformed design information, such as a GDSII file 1126 that includes information describing the heterogeneous cell array 100 of FIG. 1, in addition to other circuits or information. To illustrate, the data file may include information corresponding to a system-on-chip (SOC) that includes the heterogeneous cell array 100 of FIG. 1, and that also includes additional electronic circuits and components within the SOC.

The GDSII file 1126 may be received at a fabrication process 1128 to manufacture the heterogeneous cell array 100 of FIG. 1, according to transformed information in the GDSII file 1126. For example, a device manufacture process may include providing the GDSII file 1126 to a mask manufacturer 1130 to create one or more masks, such as masks to be used with photolithography processing, illustrated as a representative mask 1132. The mask 1132 may be used during the fabrication process to generate one or more wafers 1134, which may be tested and separated into dies, such as a representative die 1136. The die 1136 includes a circuit including the heterogeneous cell array 100 of FIG. 1.

For example, the fabrication process 1128 may include a processor 1127 and a memory 1129 to initiate and/or control the fabrication process 1128. The memory 1129 may include executable instructions such as computer-readable instructions or processor-readable instructions. The executable instructions may include one or more instructions that are executable by a computer such as the processor 1127. In a particular implementation, the executable instructions may cause a computer to perform the process 1100 of FIG. 11 or at least a portion thereof.

The fabrication process 1128 may be implemented by a fabrication system that is fully automated or partially automated. For example, the fabrication process 1128 may be automated according to a schedule. The fabrication system may include fabrication equipment (e.g., processing tools) to perform one or more operations to form a semiconductor device. For example, the fabrication equipment may be configured to deposit one or more materials using chemical vapor deposition (CVD), physical vapor deposition (PVD), or ALD. As a further example, the fabrication equipment may, additionally or alternatively, be configured to apply a hardmask, to apply an etching mask, to perform etching, to perform planarization, to form a gate stack, and/or to perform a standard clean 1 type or a standard clean 2 type. In a particular implementation, the fabrication process 1128 corresponds to a semiconductor manufacturing process associated with a technology node smaller than 14 nm (e.g., 10 nm, 7 nm, etc.). The specific process or combination of processes used to manufacture a device, such as the heterogeneous cell array 100 of FIG. 1, may be based on design constraints and available materials/equipment.

The fabrication system (e.g., an automated system that performs the fabrication process 1128) may have a distributed architecture (e.g., a hierarchy). For example, the fabrication system may include one or more processors, such as the processor 1127, one or more memories, such as the memory 1129, and/or controllers that are distributed according to the distributed architecture. The distributed architecture may include a high-level processor that controls or initiates operations of one or more low-level systems. For example, a high-level portion of the fabrication process 1128 may include one or more processors, such as the processor 1127, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level. Each of the one or more low-level systems may be associated with one or more corresponding pieces of fabrication equipment (e.g., processing tools). In a particular implementation, the fabrication system may include multiple processors that are distributed in the fabrication system. For example, a controller of a low-level system component may include a processor, such as the processor 1127.

Alternatively, the processor 1127 may be a part of a high-level system, subsystem, or component of the fabrication system. In another implementation, the processor 1127 includes distributed processing at various levels and components of a fabrication system.

The executable instructions included in the memory 1129 may enable the processor 1127 to form (or to initiate formation of) the heterogeneous cell array 100 of FIG. 1. In a particular implementation, the memory 1129 is a non-transitory computer-readable medium storing computer-executable instructions or commands that are executable by the processor 1127 to cause the processor 1127 to initiate formation of a heterogeneous cell array in accordance with at least a portion of the method 900 of FIG. 9.

The die 1136 may be provided to a packaging process 1138 where the die 1136 is incorporated into a representative package 1140. For example, the package 1140 may include the single die 1136 or multiple dies, such as a system-in-package (SiP) arrangement. The package 1140 may be configured to conform to one or more standards or specifications, such as Joint Electron Device Engineering Council (JEDEC) standards.

Information regarding the package 1140 may be distributed to various product designers, such as via a component library stored at a computer 1146. The computer 1146 may include a processor 1148, such as one or more processing cores, coupled to a memory 1150. A printed circuit board (PCB) tool may be stored as processor executable instructions at the memory 1150 to process PCB design information 1142 received from a user of the computer 1146 via a user interface 1144. The PCB design information 1142 may include physical positioning information of a packaged semiconductor device on a circuit board, the packaged semiconductor device corresponding to the package 1140 including the heterogeneous cell array 100 of FIG. 1.

The computer 1146 may be configured to transform the PCB design information 1142 to generate a data file, such as a GERBER file 1152 with data that includes physical positioning information of a packaged semiconductor device on a circuit board, as well as layout of electrical connections such as traces and vias, where the packaged semiconductor device corresponds to the package 1140 including the heterogeneous cell array 100 of FIG. 1. In other implementations, the data file generated by the transformed PCB design information may have a format other than a GERBER format.

The GERBER file 1152 may be received at a board assembly process 1154 and used to create PCBs, such as a representative PCB 1156, manufactured in accordance with the design information stored within the GERBER file 1152. For example, the GERBER file 1152 may be uploaded to one or more machines to perform various steps of a PCB production process. The PCB 1156 may be populated with electronic components including the package 1140 to form a representative printed circuit assembly (PCA) 1158.

The PCA 1158 may be received at a product manufacture process 1160 and integrated into one or more electronic devices, such as a first representative electronic device 1162 and a second representative electronic device 1164. As an illustrative, non-limiting example, the first representative electronic device 1162, the second representative electronic device 1164, or both, may be selected from the group of a set top box, a music player, a video player, an entertainment unit, a navigation device, a communications device, a personal digital assistant (PDA), a fixed location data unit, and a computer, into which the heterogeneous cell array 100 of FIG. 1 is integrated. As another illustrative, non-limiting example, one or more of the electronic devices 1162 and 1164 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 11 illustrates remote units according to teachings of the disclosure, the disclosure is not limited to these illustrated units. Implementations of the disclosure may be suitably employed in any device which includes active integrated circuitry including memory and on-chip circuitry. For example, one or more of the electronic devices 1162 and 1164 may include cars, trucks, airplanes, boats, drones, other vehicles, or appliances, such as refrigerators, microwaves, washing machines, security systems, or a combination thereof. In a particular implementation, one or more of the electronic devices 1162 and 1164 may utilize memory and/or wireless communication.

A device, such as the heterogeneous cell array 100 of FIG. 1, may be fabricated, processed, and incorporated into an electronic device, as described in the illustrative process 1100 of FIG. 11. One or more aspects of the implementations disclosed herein may be included at various processing stages, such as within the library file 1112, the GDSII file 1126, and the GERBER file 1152, as well as stored at the memory 1110 of the research computer 1106, the memory 1118 of the design computer 1114, the memory 1150 of the computer 1146, the memory of one or more other computers or processors (not shown) used at the various stages, such as at the board assembly process 1154, and also incorporated into one or more other physical implementations such as the mask 1132, the die 1136, the package 1140, the PCA 1158, other products such as prototype circuits or devices (not shown), or any combination thereof. Although various representative stages of production from a physical device design to a final product are depicted, in other implementations fewer stages may be used or additional stages may be included. Similarly, the process 1100 may be performed by a single entity or by one or more entities performing various stages of the process 1100.

Those of skill would further appreciate that the various illustrative logical blocks, configurations, modules, circuits, and algorithm steps described in connection with the implementations disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the implementations disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed implementations is provided to enable a person skilled in the art to make or use the disclosed implementations. Various modifications to these implementations will be readily apparent to those skilled in the art, and the principles defined herein may be applied to other implementations without departing from the scope of the disclosure. Thus, the present disclosure is not intended to be limited to the implementations shown herein but is to be accorded the widest scope possible consistent with the principles and novel features as defined by the following claims.

1. A heterogeneous cell array comprising:
a first column of cells comprising:
a first cell having a first area, the first cell comprising two fin-type field effect transistors having a first number of fins; and
a second cell having the first area, the second cell comprising two fin-type field effect transistors having the first number of fins; and
a second column of cells comprising a third cell having a second area, the third cell adjacent to the first cell and to the second cell, wherein the third cell comprises two fin-type field effect transistors having a second number of fins,
wherein the second area is greater than the first area, and wherein the second number of fins is greater than the first number of fins.

2. The heterogeneous cell array of claim 1, wherein the first area is substantially rectangular having a first length and a first width, and wherein the second area is substantially rectangular having a second length and the first width.

3. The heterogeneous cell array of claim 2, wherein the second length is about twice the first length.

4. The heterogeneous cell array of claim 1, wherein the two fin-type field effect transistors of the first cell comprise:
a first p-type metal oxide semiconductor transistor; and
a first n-type metal oxide semiconductor transistor.

5. The heterogeneous cell array of claim 4, wherein the two fin-type field effect transistors of the cell comprise:
a second n-type metal oxide semiconductor transistor; and
a second p-type metal oxide semiconductor transistor.

6. The heterogeneous cell array of claim 5, wherein the two fin-type field effect transistors of the third cell comprise:
a third p-type metal oxide semiconductor transistor; and
a third n-type metal oxide semiconductor transistor.

7. The heterogeneous cell array of claim 6, further comprising:
a first power grid line coupled to the first p-type metal oxide semiconductor transistor and to the third p-type metal oxide;
a second power grid line coupled to the first n-type metal oxide semiconductor transistor and to the second n-type metal oxide semiconductor transistor;
a third power grid line coupled to the second p-type metal oxide semiconductor transistor; and
a fourth power grid line coupled to the third n-type metal oxide semiconductor transistor.

8. The heterogeneous cell array of claim 7, wherein the first power grid line and the third power grid line have a logical low voltage level, and wherein the second power grid line and the fourth power grid line have a logical high voltage level.

9. The heterogeneous cell array of claim 7, wherein the third power grid line and the fourth power grid line are formed using a common metal layer that is cut according to a power grid cut pattern.

10. The heterogeneous cell array of claim 1, wherein the second area is about three times the first area.

11. A method for forming a heterogeneous cell array, the method comprising:
forming a first column of cells comprising:
a first cell having a first area, the first cell comprising two fin-type field effect transistors having a first number of fins; and
a second cell having the first area, the second cell comprising two fin-type field effect transistors having the first number of fins; and
forming a second column of cells comprising a third cell having a second area, the third cell adjacent to the first cell and to the second cell, wherein the third cell comprises two fin-type field effect transistors having a second number of fins,
wherein the second area is greater than the first area, and wherein the second number of fins is greater than the first number of fins.

12. The method of claim 11, wherein the first area is substantially rectangular having a first length and a first width, and wherein the second area is substantially rectangular having a second length and the first width.

13. The method of claim 12, wherein the second length is about twice the first length.

14. The method of claim 11, wherein the two fin-type field effect transistors of the first cell comprise:
a first p-type metal oxide semiconductor transistor; and
a first n-type metal oxide semiconductor transistor.

15. The method of claim 14, wherein the two fin-type field effect transistors of the cell comprise:
a second n-type metal oxide semiconductor transistor; and
a second p-type metal oxide semiconductor transistor.

16. The method of claim 15, wherein the two fin-type field effect transistors of the third cell comprise:
a third p-type metal oxide semiconductor transistor; and
a third n-type metal oxide semiconductor transistor.

17. The method of claim 16, further comprising:
coupling a first power grid line to the first p-type metal oxide semiconductor transistor and to the third p-type metal oxide;
coupling a second power grid line to the first n-type metal oxide semiconductor transistor and to the second n-type metal oxide semiconductor transistor;
coupling a third power grid line to the second p-type metal oxide semiconductor transistor; and
coupling a fourth power grid line to the third n-type metal oxide semiconductor transistor.

18. The method of claim 17, wherein the first power grid line and the third power grid line have a logical low voltage level, and wherein the second power grid line and the fourth power grid line have a logical high voltage level.

19. The method of claim 17, wherein the third power grid line and the fourth power grid line are formed using a common metal layer that is cut according to a power grid cut pattern.

20. The method of claim 11, wherein the second area is about three times the first area.

21. A non-transitory computer-readable medium comprising commands for forming a heterogeneous cell array, the commands, when executed by a fabrication device, cause the fabrication device to perform operations comprising:
forming a first column of cells comprising:
a first cell having a first area, the first cell comprising two fin-type field effect transistors having a first number of fins; and
a second cell having the first area, the second cell comprising two fin-type field effect transistors having the first number of fins; and
forming a second column of cells comprising a third cell having a second area, the third cell adjacent to the first cell and to the second cell, wherein the third cell comprises two fin-type field effect transistors having a second number of fins,
wherein the second area is greater than the first area, and wherein the second number of fins is greater than the first number of fins.

22. The non-transitory computer-readable medium of claim 21, wherein the first area is substantially rectangular having a first length and a first width, and wherein the second area is substantially rectangular having a second length and the first width.

23. The non-transitory computer-readable medium of claim 22, wherein the second length is about twice the first length.

24. The non-transitory computer-readable medium of claim 21, wherein the two fin-type field effect transistors of the first cell comprise:
a first p-type metal oxide semiconductor transistor; and
a first n-type metal oxide semiconductor transistor.

25. The non-transitory computer-readable medium of claim 24, wherein the two fin-type field effect transistors of the cell comprise:
a second n-type metal oxide semiconductor transistor; and
a second p-type metal oxide semiconductor transistor.

26. The non-transitory computer-readable medium of claim 25, wherein the two fin-type field effect transistors of the third cell comprise:
a third p-type metal oxide semiconductor transistor; and
a third n-type metal oxide semiconductor transistor.

27. The non-transitory computer-readable medium of claim 26, wherein the operations further comprise:
coupling a first power grid line to the first p-type metal oxide semiconductor transistor and to the third p-type metal oxide;
coupling a second power grid line to the first n-type metal oxide semiconductor transistor and to the second n-type metal oxide semiconductor transistor;
coupling a third power grid line to the second p-type metal oxide semiconductor transistor; and
coupling a fourth power grid line to the third n-type metal oxide semiconductor transistor.

28. The non-transitory computer-readable medium of claim 27, wherein the first power grid line and the third power grid line have a logical low voltage level, and wherein the second power grid line and the fourth power grid line have a logical high voltage level.

29. A heterogeneous cell array comprising:
a first column comprising:
first means for aligning circuit components to a power grid having a first area, the first means for aligning circuit components to the power grid comprising two fin-type field effect transistors having a first number of fins; and
second means for aligning circuit components to the power grid having the first area, the second means for aligning circuit components to the power grid comprising two fin-type field effect transistors having the first number of fins; and
a second column comprising third means for aligning circuit components to the power grid having a second area, the third means for aligning circuit components to the power grid adjacent to the first means for aligning circuit components to the power grid and to the second means for aligning circuit components to the power grid, wherein the third means for aligning circuit components to the power grid comprises two fin-type field effect transistors having a second number of fins,
wherein the second area is greater than the first area, and wherein the second number of fins is greater than the first number of fins.

30. The heterogeneous cell array of claim 29, wherein the first area is substantially rectangular having a first length and a first width, and wherein the second area is substantially rectangular having a second length and the first width.
